(19) United States
(12) Patent Application Publication
(10) Pub. No.: US 2012/0104543 A1
(43) Pub. Date: May 3, 2012

(54) HIGH-SPEED MEMORY SOCKETS AND INTERPOSERS

(75) Inventor: Erik James Shahoian, Orinda, CA (US)

(73) Assignee: Apple Inc., Cupertino, CA (US)

(21) Appl. No.: 13/249,260

(22) Filed: Sep. 30, 2011

Related U.S. Application Data
(60) Provisional application No. 61/408,147, filed on Oct. 29, 2010.

(51) Int. Cl. H01L 27/02; H01L 23/498

(52) U.S. Cl. 257/528; 257/738; 257/E27.009; 257/E23.069

(57) ABSTRACT

High-speed memory systems that consume a reduced amount of board space, have a low height or profile, or both. This reduction in board space and height may result in shorter signal paths from a board to a memory device, thereby improving the high-speed performance of the high-speed memory system. One example may provide a space-efficient memory system that consumes a reduced amount of board space. Space efficiency may gained by arraying memory devices on an interposer that mates with a socket attached to a board. Another example may provide a memory system that has a reduced height or profile. This reduced height may be achieved by employing a socket that accepts an interposer in a lateral or rotational direction.

### CROSS-REFERENCES TO RELATED APPLICATIONS

This application claims the benefit of U.S. provisional patent application No. 61/408,147, filed Oct. 29, 2010, which is incorporated by reference.

### BACKGROUND

The number and types of electronic devices that are available to consumers has skyrocketed in recent years, and this increase shows no signs of abating. Laptop, netbook, desktop, tablet, and other computers, media players, portable media players, cell, media, and smart phones, and other devices have become ubiquitous.

These devices require memory for storing data. Often this memory is realized in the form of a memory system that includes a card or board that may be inserted into a socket on a main or motherboard. Specifically, the card or board may include a number of memory devices. The card or board may be inserted into a socket that is fixed on a printed circuit board. This arrangement allows the memory to be replaced if it is, or becomes, defective. It also allows a user to upgrade the memory as the user's needs change.

But these boards and sockets consume space in these electronic devices. This space may be in the form of area on a main or motherboard. The consumption of this main or motherboard area means that the electronic device either needs to be made larger to accommodate the boards and sockets, or the device may have a reduced functionality (or a combination of both)

This space may also or alternatively be in the form of an increased height or profile. This increased height or profile means that the electronic device may need to have an increased thickness.

Moreover, these boards and sockets may have long signal traces between the memory devices and components on a main or motherboard. These relatively long traces may increase coupling between signals, increase insertion losses, and degrade signal quality.

Accordingly, what is needed are high-speed memory systems that have a reduced size. This reduction in size may be in terms of board area consumed by the memory system, the height of the memory system, or both.

### SUMMARY

Accordingly, embodiments of the present invention may provide high-speed memory systems that have a reduced size. This reduction in size may be in terms of board space consumed, or reduced height or profile, or both. This reduction in board space and height may result in shorter signal paths from a board to a memory device, thereby improving the high-speed performance of the high-speed memory system.

An exemplary embodiment of the present invention may provide a space-efficient memory system that consumes a reduced amount of board space. Space efficiency may be gained by arraying memory devices on an interposer that mates with a socket attached to a board.

In various embodiments of the present invention, the memory devices may be single memory chips, single packaged memories, stacked memory chips, stacked packaged memories, or other type of memory device. The memories may be arrayed in a square, rectangular, circular, or other manner. The array of memory devices may have openings for control, passive, or other components that may be required for operation of the memory devices.

In various embodiments of the present invention, the interposer may be a printed circuit board or other appropriate substrate. The interposer may include traces on one or more layers to provide electrical connections between the memory devices and pins of the socket. Various embodiments of the present invention may provide interposer and socket combinations that have a reduced signal path length. This may lead to increased signal quality, reduced cross talk, and reduced insertion losses. In various embodiments of the present invention, these interposers may be at least approximately square, rectangular, circular, or they may have other shapes.

In various embodiments of the present invention, the socket may be an FPGA ball grid array socket or other type of socket. The socket may be fixed to a motherboard of a desktop, laptop, netbook, tablet, or other type of computer, media device, portable media device or player, daughter board, or other type of board or card.

Another exemplary embodiment of the present invention may provide a memory system that has a reduced height or profile. This reduced height may be achieved by employing a socket that accepts an interposer in a lateral or rotational direction.

In one specific embodiment of the present invention, the socket and interposer may be at least approximately square or rectangular in shape. The interposer may have a number of memory devices and control, passive, or other components on a top side and a number of contacts on a bottom side. The interposer may be inserted in the socket by moving in a primarily lateral direction. Once inserted, the interposer may be held in place by tabs or flanges.

In another specific embodiment of the present invention, the socket and interposer may be at least approximately circular in shape. The interposer may have a number of memory devices and control, passive, or other components on a top side and a number of contacts on a bottom side. The interposer may be placed in the socket and rotated until properly inserted. Once inserted, the interposer may be held in place by tabs or flanges.

In various embodiments of the present invention, high-speed performance may be improved by reducing the length of signal paths from a board to a memory device. This reduction may occur as a result of the reduction of the size and height of memory systems consistent with embodiments of the present invention. Again, this may lead to increased signal quality, reduced cross talk, and reduced insertion losses.

Various embodiments of the present invention may incorporate one or more of these and the other features described herein. A better understanding of the nature and advantages of the present invention may be gained by reference to the following detailed description and the accompanying drawings.

### BRIEF DESCRIPTION OF THE DRAWINGS

FIG. 1 illustrates a high-speed memory system according to an embodiment of the present invention;

FIG. 2 illustrates another memory system according to an embodiment of the present invention;

FIG. 3 illustrates a memory system according to an embodiment of the present invention;

FIG. 4 illustrates the insertion of an interposer into a socket of a memory system according to an embodiment of the present invention;

FIG. 5 illustrates a memory system according to an embodiment of the present invention;

FIG. 6 illustrates a memory system according to an embodiment of the present invention;

FIG. 7 illustrates a circular socket consistent with an embodiment of the present invention;

FIG. 8 illustrates a bottom of a circular interposer according to an embodiment of the present invention; and

FIG. 9 illustrates electrical connections formed between and interposer and a socket according to an embodiment of the present invention.

### DESCRIPTION OF EXEMPLARY EMBODIMENTS

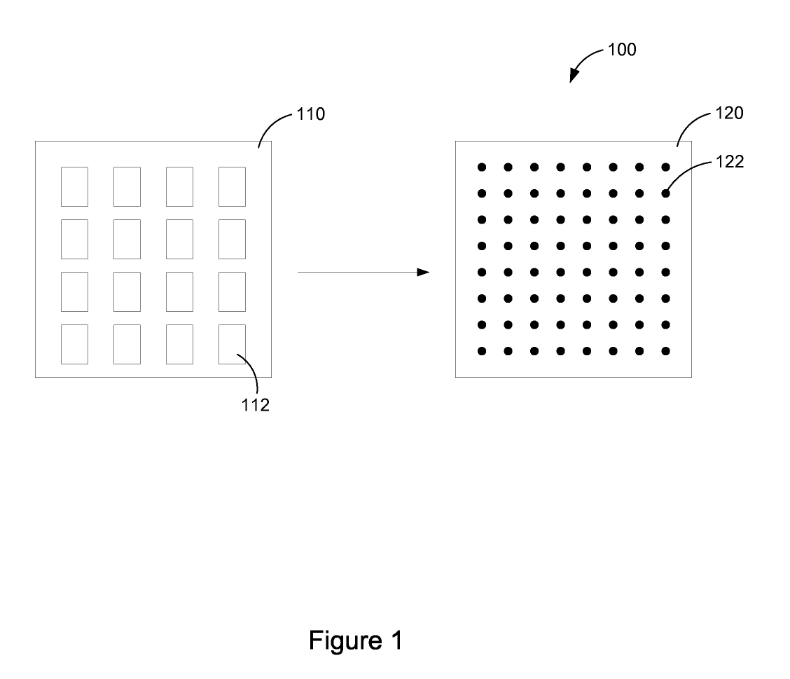

FIG. 1 illustrates a high-speed memory system according to an embodiment of the present invention. This figure, as with the other included figures, is shown for illustrative purposes and does not limit either the possible embodiments of the present invention or the claims. High-speed memory system 100 may include interposer 110 and socket 120. Interposer 110 may be arranged to mate with socket 120.

Interposer 110 may include a number of memory devices 112 on a top surface. In various embodiments of the present invention, memory devices, such as memory devices 112, may be integrated circuit chips that are not packaged and are directly placed on interposer 120 or another substrate attached to interposer 120. In such a situation, interposer 110 may include a cover (not shown), to protect memory devices 112. In other embodiments of the present invention, memory devices 112 may be packaged integrated circuits. In still other embodiments of the present invention, memory devices 112 may be either stacked die or packaged integrated circuits. The top surface of interposer 110 may also include control circuits, passive component, or other circuitry for the operation of memory devices 112. These passive components may include resistors and power supply decoupling capacitors. Other circuitry for other functions either related to, or separate from, memory devices 112 may also be included on one or both sides of interposer 110.

A bottom of interposer 110 may include a number of contacts. These contacts may be pins or balls arrayed as a pin grid array or ball grid array, though in various embodiments of the present invention, they may have different arrangements and they may be different types of contacts. In various embodiment of the present invention, interposer 110 may include an excess number of contacts over what is needed to support memory devices 112 and other circuitry that may be included on interposer 110. These extra contacts may be used as a thermal vias to dissipate heat from memory devices 112. These extra contacts may also be used as ground connections to provide isolation between signal pins.

Interposer 110 may include a number of traces connecting memory devices 112 to contacts on a bottom of interposer 110. These traces may be routed through interposer 110 on its various layers. Since the size of interposer 110 and socket 120 are reduced, trace lengths from memory devices 112 to pins of socket 120 may be shortened. This shortening may reduce cross-talk between signal lines, reduces insertion losses, and improve signal quality. Interposer 110 may be formed as a multilayer printed circuit board, hybrid device package, or other appropriate structure.

The contacts of interposer 110 may be arranged to mate with contacts 122 on socket 120. Socket 120 may be fixed to a board, such as a main or motherboard. This main or motherboard may be located in a laptop, netbook, desktop, tablet, or other type of computer, media player, portable media player, cell, media, or smart phone, or other type of electronic device. In various embodiments of the present invention, a processor may be placed on the other side of the main or motherboard away from socket 122. This provides a short path from the processor to memory devices 112.

In this example, interposer 110 has a similar size as socket 120. In other embodiments of the present invention, interposer 110 may be larger than socket 120. For example, interposer 110 may extend beyond one or more edges of socket 120. This allows a larger topside surface area for interposer 110, which increases the number of memory devices 112 or other circuits that may be supported. Additional memory devices 112 or other circuitry may also be included on an underside of the overhanging portion of interposer 110. In embodiments of the present invention where one or more edges of interposer 110 extends beyond edges of socket 120, area on the main or motherboard below the overhanging portion of interposer 110 may be populated with components, traces, or other circuitry.

Memory system 100 may provide an efficient memory arrangement that reduces the amount of board area consumed. This may be achieved by arraying memory devices 112 in an efficient manner. In some embodiments the present invention, portions of the array may be omitted to provide space for other active circuitry or passive components. This circuitry may support the functionality of memory devices 112, or they may provide other functions. An example of an embodiment of the present invention where portions of an array of memory devices are omitted is shown in the following figure.

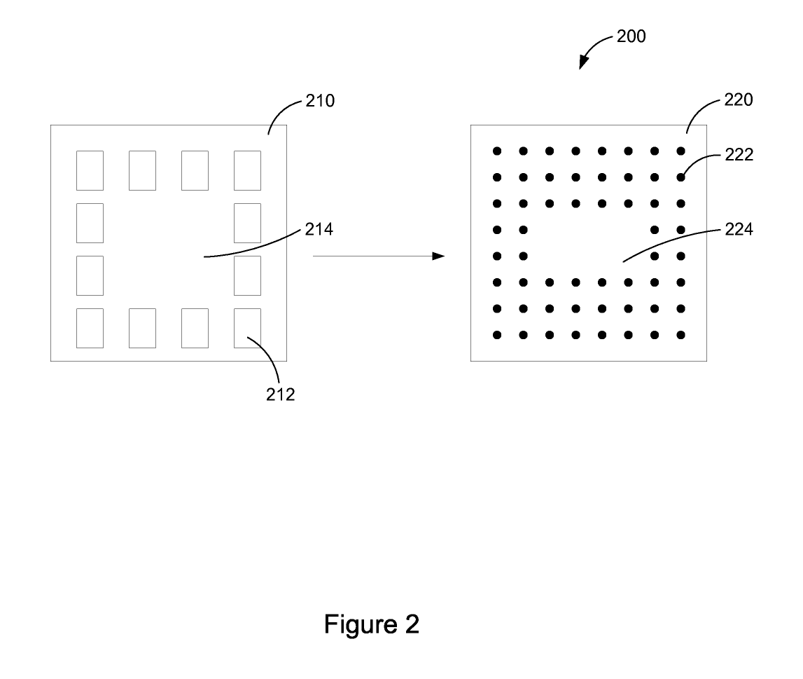

FIG. 2 illustrates another memory system according to an embodiment of the present invention. Memory system 200 may include interposer 210 and socket 220. Interposer 210 may include a number of memory devices 212. As before, memory devices 212 may be arrayed in a space efficient manner. This arrangement may be interrupted by one or more open spaces 214. These open spaces may be used as locations for control circuits, passive component, or other circuitry. This circuitry may be used for the operation of memory devices 212, or for other purposes.

Socket 220 may include a number of contacts 222. Socket 220 may also include one or more open areas 224. These open areas may provide room for circuitry which may be located on a bottom of interposer 210.

In various embodiment of the present invention, sockets 120 and 220 may be ball grid array sockets, pin grid array sockets, or other type of sockets. In various embodiment of the present invention, these may be sockets conventionally used for central processing units, graphics processing units, or other types of circuits or processors. Often these sockets provide a vertical clamping force to maintain connections between contacts on a device in the socket and contacts of the socket. The addition of mechanical components to provide this vertical clamping force may increase the height of sockets 120 and 220. Again, this increase in height may require an electronic device including these memory systems to have an increased thickness. Accordingly, other embodiments of the present invention may replace this vertical clamping force by a lateral force. This may provide a memory system having a consistent height. Examples are shown in the following figures.

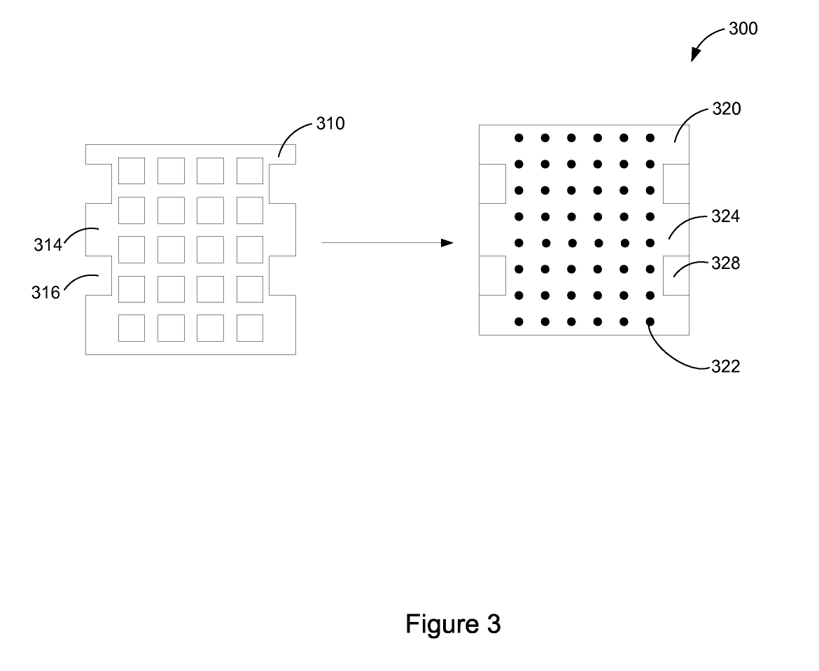

FIG. 3 illustrates a memory system according to an embodiment of the present invention. Memory system 300 may include interposer 310 and socket 320. Interposer 310 may include a number of memory devices 312. Again, memory devices 312 may be arrayed in an efficient manner to save board space. As before, memory devices 312 may be integrated circuit chips that are not packaged and are directly placed on interposer 320 or another substrate attached to interposer 320. In such a situation, interposer 310 may include a cover (not shown), to protect memory devices 312. In other embodiments of the present invention, memory devices 312 may be packaged integrated circuits. In still other embodiments of the present invention, memory devices 312 may be either stacked die or packaged integrated circuits. The top surface of interposer 310 may also include control circuits, passive component, or other circuitry for the operation of memory devices 312. These passive components may include resistors and power supply decoupling capacitors. Other circuitry for other functions either related to, or separate from, memory devices 312 may also be included on one or both sides of interposer 310.

Socket 320 may include a number of contacts 322. As before, contacts on a bottom of interposer 310 may mate with contacts 322 in socket 320 to form electrical pathways between memory devices 312 and circuitry on a main or mother board. Signal traces from memory devices 312 to pins of socket 320 may be shortened. The shortening in this and various other embodiments of the present invention may provide increase signal quality, reduced insertion losses, and reduced signal cross-talk.

Interposer 310 may include a number of tabs 314. These tabs 314 may define openings 316 between tabs 314. Openings 316 may be arranged to match flanges 326 on socket 320. That is, interposer 320 may be mated with socket 320 by aligning tabs 314 on interposer 310 with openings 324 between flanges 326 on socket 320. Similarly, flanges 326 on socket 320 may fit in openings 316 between tabs 314 on interposer 310. An example is shown in the following figure.

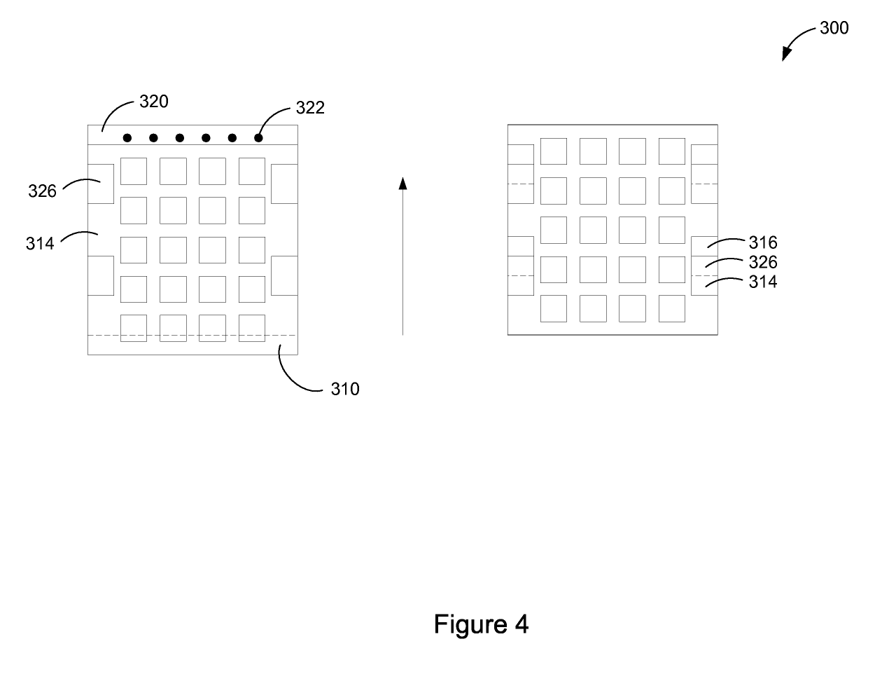

FIG. 4 illustrates the insertion of an interposer into a socket of a memory system according to an embodiment of the present invention. In this figure, tabs 314 on interposer 310 may fit between flanges 326 on socket 320. Once in place, interposer 310 may be moved laterally relative to socket 320. In this way, interposer 310 may be seated in socket 320. Specifically, tabs 314 on interposer 310 may slide under flanges 326 on socket 320. Flanges 326 may include stops (not shown) to limit the lateral movement of interposer 310 relative to socket 320 to ensure that interposer 310 is properly aligned with socket 320. Flanges 326 hold tabs 314 on interposer 310, which secures interposer 310 in place relative to socket 320.

As interposer 310 is moved laterally relative to socket 320, contacts on a bottom side of interposer 310 may make temporary electrical connections with one or more contacts on socket 320. Accordingly, various embodiments of the present invention take measures to ensure that these temporary electrical connections do not damage circuitry in, or associated with, memory system 300. In various embodiments of the present invention, power may be disconnected to the memory system while interposer 310 is inserted into socket 320. In still other embodiments of the present invention, the functionality associated with contacts on interposer 310 may be arranged such that these temporary electrical connections do not cause damage. In still other embodiments of the present invention, contacts 322 are arranged having and enough space between rows such that these temporary electrical connections are not created.

In this specific embodiment of the present invention, interposer 310 may be sized to approximately match socket 320. As before, in other embodiments of the present invention, one or more edges of interposer 310 may be extended to overhang edges of socket 320. An example is shown in the following figure.

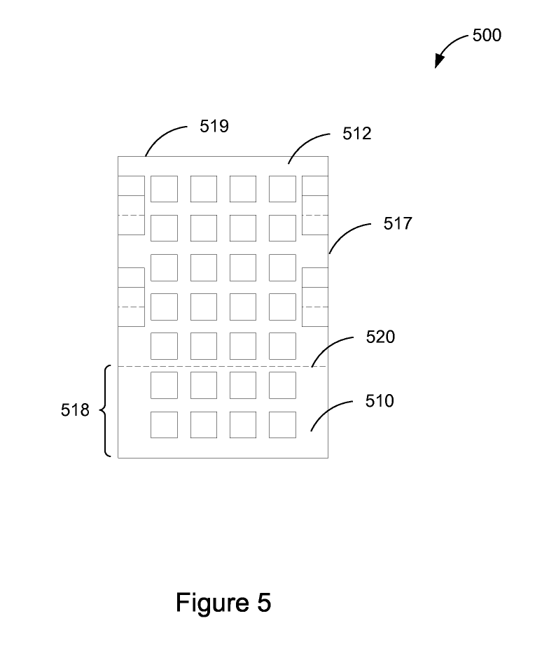

FIG. 5 illustrates a memory system according to an embodiment of the present invention. Memory system 500 may include interposer 510 and socket 520. As before, interposer 510 may include a number of memory devices 512. Interposer 510 may include an overhang portion 518 that extends beyond an edge of socket 520. Overhang portion 518 may be used to support additional memory devices 512. These additional memory devices 512 may be located either on a top or a bottom of overhang portion 518. Space on a board below overhang portion 518 may be populated with active circuitry, passive component, traces, or other electrical components.

While in this example, portion 518 overhangs an edge of socket 520, in other embodiments of the present invention, other edges of interpose 510 may be extended to create portions of interposer 510 that overhang socket 520. For example, edges 517, 519, or other edges of interposer 510 may overhang, or extend beyond, edges of socket 520.

In the above embodiments of the present invention, interposer 310 and socket 320 are shown as being at least approximately square or rectangular in shape. The forces provided by flanges 326 onto tabs 314 on interposer 310 may cause interposer 310 two bend or otherwise distort. Interposer 310 may need to have an increased thickness to support these forces. These forces may be more evenly distributed in a circular memory system, which may allow interposers 310 to have a reduced thickness, which in turn may result in a reduced profile or height for the memory system. An example is shown in the following figure.

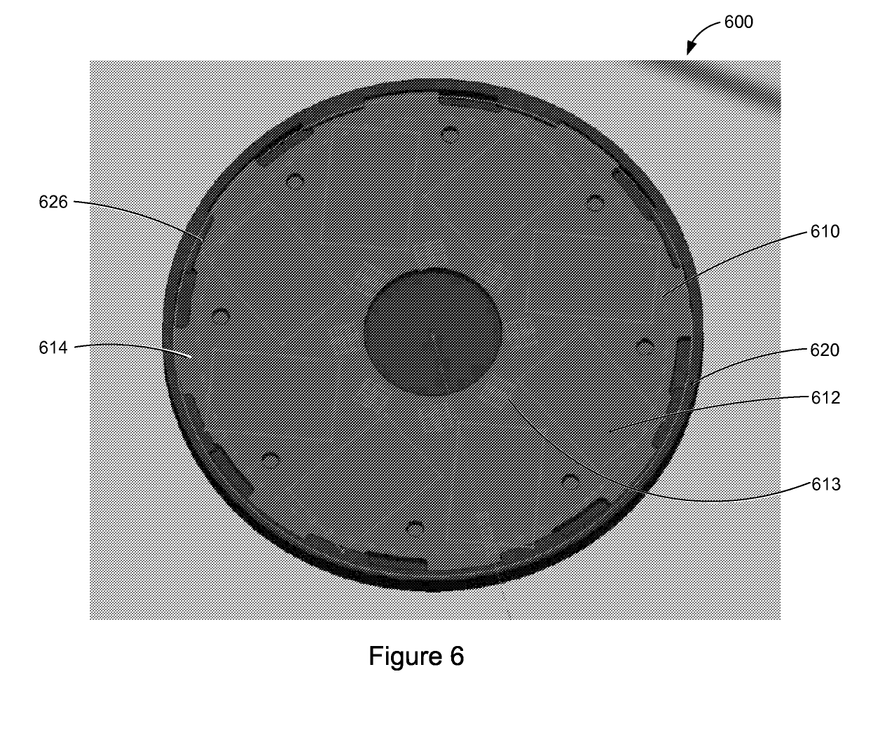

FIG. 6 illustrates a memory system according to an embodiment of the present invention. Memory system 600 may include interposer 610 and socket 620. Interposer 610 may include a number of memory devices 612 as well as control, passive, or other components 613. As before, memory devices 612 may be integrated circuit chips that are not packaged and are directly placed on interposer 620 or another substrate attached to interposer 620. In such a situation, interposer 610 may include a cover (not shown), to protect memory devices 612. In other embodiments of the present invention, memory devices 612 may be packaged integrated circuits. In still other embodiments of the present invention, memory devices 612 may be either stacked die or packaged integrated circuits. The top surface of interposer 610 may also include control circuits, passive component, or other circuitry for the operation of memory devices 612. These passive components may include resistors and power supply decoupling capacitors. Other circuitry for other functions either related to, or separate from, memory devices 612 may also be included on one or both sides of interposer 610.

Tabs 614 on interposer 610 may be arranged to fit between flanges 626 on socket 620. Once interposer 610 is placed in socket 620, interposer 610 may be rotated, in this example counter clockwise, and seated or inserted in socket 620. Specifically, tabs 614 on interposer 610 may slide under flanges 626 on socket 620. Flanges 626 may include stops (not shown) to ensure that interposer 610 is correctly aligned with socket 620 when inserted. This may allow contacts on a bottom of interposer 610 to mate with contacts in socket 620. In this way, holding forces provided by flanges 626 on tabs 614 of interposer 610 may be distributed around an edge of interposer 610. This may reduce the tendency of interposer 610 to warp, bend, or distort. This in turn may allow interposer 610 to have a reduced thickness.

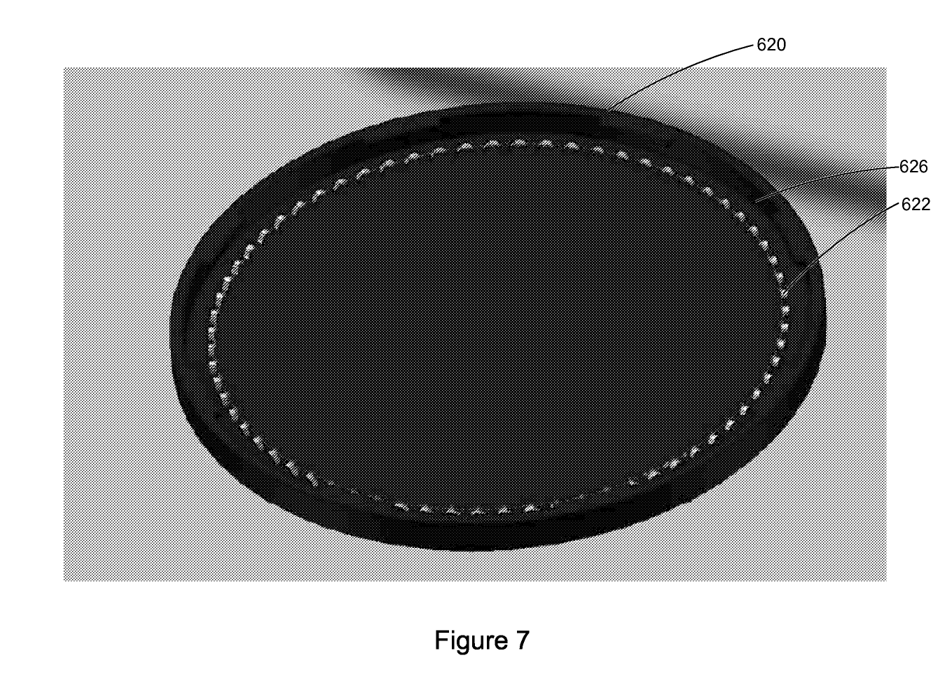

FIG. 7 illustrates a circular socket consistent with an embodiment of the present invention. Socket 620 may include a number of flanges 626 placed around an edge. Once an interposer is inserted into socket 620, tabs of the interposer may slide under flanges 626. This may hold the interposer in place in socket 620. Flanges 626 may include stops (not shown) to ensure that interpose 610 is properly aligned when inserted into socket 620. Socket 620 may include a number of contacts 622, only a few of which are shown for clarity. Contacts 622 may be arranged in a circular manner, or they may be arranged in other patterns.

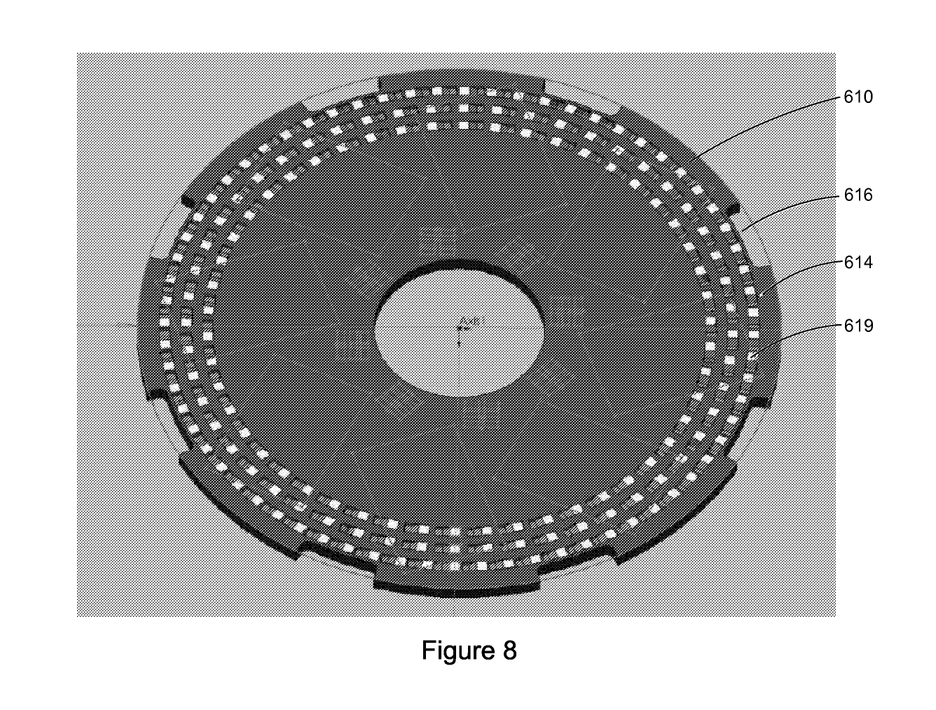

FIG. 8 illustrates a bottom of a circular interposer according to an embodiment of the present invention. Interposer 610 may include a number of tabs 614. Tabs 614 may define open spaces 616. Open spaces 616 may be aligned with flanges 626 on socket 620. Interposer 610 may then be seated or inserted into socket 620 by rotating interposer 610 such that tabs 614 slide under flanges 626 on socket 620.

Interposer 610 may include a number of contacts 619. Contacts 619 may be arranged in a circular or other manner. These contacts may have a ramp shape to mate with spring contacts on socket 620. An example is shown in the following figure.

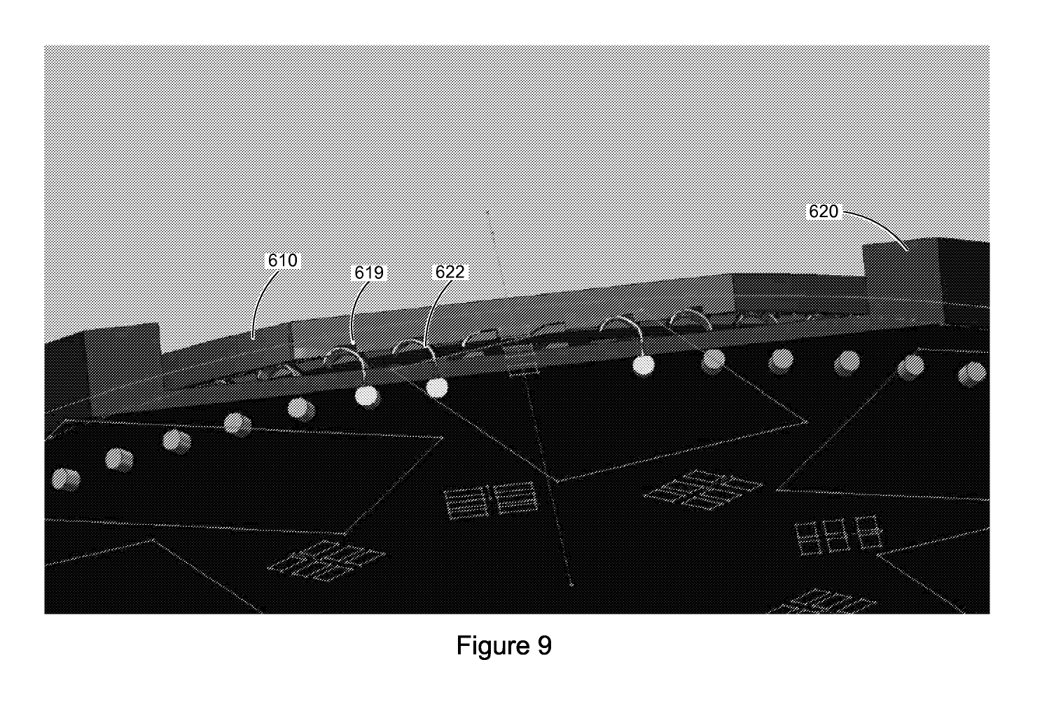

FIG. 9 illustrates electrical connections formed between and interposer and a socket according to an embodiment of the present invention. Specifically, this figure illustrates a connection between contacts 619 on interposer 610 and contacts 622 on socket 620. In this figure, portions of interposer 610 and socket 620 have been removed to illustrate contacts 619 on interposer 610 and contacts 622 on socket 620 more clearly. As interposer 610 is rotated relative to socket 620, spring contacts 622 may be compressed and may form electrical connects with contacts 619 on interposer 610.

As before, interposer 610 may rotate through an angle such that a particular contact 622 on socket 620 may form temporary electrical connections with one or more contacts 619 on interposer 610. Accordingly, various embodiments of the present invention take measures to ensure that these temporary electrical connections do not damage circuitry in, or associated with, memory system 600. In various embodiments of the present invention, power may be disconnected to the memory system while interposer 610 is inserted into socket 620. In still other embodiments of the present invention, the functionality associated with contacts 619 on interposer 610 is arranged such that these temporary electrical connections do not cause damage. In still other embodiments of the present invention, contacts 619 and 622 are arranged having and enough space between themselves such that these temporary electrical connections are not created.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

What is claimed is:

1. A high-speed memory system comprising:
an interposer having a plurality of contacts arranged as a ball grid array on a bottom side;
a plurality of memory devices arrayed on a top side of the interposer; and
a socket having a plurality of contacts to mate with the ball grid array contacts on the bottom side of the interposer.

2. The high-speed memory system of claim 1 further comprising a control device on the top side of the interposer.

3. The high-speed memory system of claim 2 further comprising a plurality of passive components on the top side the interposer.

4. The high-speed memory system of claim 1 wherein the plurality of memory devices comprises a plurality of integrated circuit chips located directly on the top side of the interposer.

5. The high-speed memory system of claim 1 wherein the plurality of memory devices comprises a plurality of packaged integrated circuit chips located on the top side of the interposer.

6. The high-speed memory system of claim 1 wherein the plurality of memory devices comprises a plurality of stacked integrated circuit chips located directly on the top side of the interposer.

7. The high-speed memory system of claim 1 wherein the plurality of memory devices comprises a plurality of stacked packaged integrated circuit chips located on the top side of the interposer.

8. The high-speed memory system of claim 1 wherein the interposer further comprises a plurality of traces to connect the memory devices to the plurality of contacts arranged as a ball grid array.

9. A high-speed memory system comprising:
an interposer having a plurality of tabs along an edge and a number of contacts on a bottom side;
a plurality of memory devices arranged on a top side of the interposer; and
a socket having a plurality of flanges, the plurality of flanges having spaces between them to accept the plurality of tabs on the edge of the interposer.

10. The high-speed memory system of claim 9 wherein the interposer may be inserted into the socket by aligning the tabs with the spaces between the flanges then moving the interposer in a lateral direction.

11. The high-speed memory system of claim 9 wherein the interposer may be inserted into the socket by aligning the tabs with the spaces between the flanges then rotating the interposer.

12. The high-speed memory system of claim 9 wherein the plurality of memory devices comprises a plurality of integrated circuit chips located directly on the top side of the interposer.

13. The high-speed memory system of claim 9 wherein the plurality of memory devices comprises a plurality of packaged integrated circuit chips located on the top side of the interposer.

14. The high-speed memory system of claim 9 wherein the plurality of memory devices comprises a plurality of stacked integrated circuit chips located directly on the top side of the interposer.

15. The high-speed memory system of claim 9 wherein the plurality of memory devices comprises a plurality of stacked packaged integrated circuit chips located on the top side of the interposer.

16. The high-speed memory system of claim 9 wherein the interposer further comprises a plurality of traces to connect the memory devices to the plurality of contacts arranged as a ball grid array.

17. An interposer for a high-speed memory system, the interposer comprising:
a plurality of memory devices arranged on a top side;
a plurality of contacts arranged as a ball grid array on a bottom side;
a plurality of traces to connect the memory devices to the plurality of contacts arranged as a ball grid array; and
a plurality of tabs along an edge arranged to mate with spaces between a plurality of flanges on a socket.

18. The interposer of claim 17 wherein the interposer may be inserted into the socket by aligning the tabs with the spaces between the flanges then moving the interposer in a lateral direction.

19. The interposer of claim 17 wherein the interposer may be inserted into the socket by aligning the tabs with the spaces between the flanges then rotating the interposer.

20. The interposer of claim 17 wherein the plurality of memory devices comprises a plurality of integrated circuit chips located directly on the top side of the interposer.

21. The interposer of claim 17 wherein the plurality of memory devices comprises a plurality of packaged integrated circuit chips located on the top side of the interposer.

22. The interposer of claim 17 wherein the plurality of memory devices comprises a plurality of stacked integrated circuit chips located directly on the top side of the interposer.

23. The interposer of claim 17 wherein the plurality of memory devices comprises a plurality of stacked packaged integrated circuit chips located on the top side of the interposer.

24. The interposer of claim 17 wherein the interposer further comprises a plurality of traces to connect the memory devices to the plurality of contacts arranged as a ball grid array.
